(19) United States
(12) Patent Application Publication
(10) Pub. No.: US 2007/0115642 A1
(43) Pub. Date: May 24, 2007

(54) Fastening member for use in a heat-dissipating device

(75) Inventor: Ching Ho, Keelung City (TW)

Correspondence Address: BIRCH STEWART KOLASCH & BIRCH, PO BOX 747, FALLS CHURCH, VA, 22040-0747, US

(73) Assignee: AMA Precision Inc.

(21) Appl. No.: 11/602,399

(22) Filed: Nov. 21, 2006

(30) Foreign Application Priority Data
Nov. 22, 2005 (TW) 94140957

(51) Int. Cl. H05K 7/20

(52) U.S. Cl. 361/710

(57) ABSTRACT

A heat-dissipating device includes: a base plate for disposing on a mounting surface, a plurality of cooling fins extending vertically from the base plate to define a first channel and a second channel on an upper surface of the base plate, and a fastening member. The fastening member includes a first portion disposed in the first channel and having an engaging element for engaging a lower surface of the base plate adjacent to one end thereof, a second portion disposed in the second channel and extending integrally from the first portion, and a third portion extending integrally from the second portion. The first and second portions are located in a plane, which cooperates with the third portion to define an angle. The third portion has a hook for securing the base plate onto the mounting surface.

### FIELD OF THE INVENTION

The invention relates to a fastening member, and more particularly to a fastening member for use in a heat-dissipating device for easily securing a base plate onto a mounting surface.

### BACKGROUND OF THE INVENTION

Technological progress in the electronic field results in wide employment of variety of chipsets in many electronic devices for computing or executing many operations. During operation of the chipset, a relatively large amount of heat is generated that may affect the stability of computing process. In order to provide a stable function of the chipset, an operation temperature is generally required. Traditionally, a heat-dissipating device is usually provided above the chipset so as to dissipate the intensive heat toward an outer environment of the electronic device.

FIG. 1 is a perspective and exploded view of a conventional heat-dissipating device 10 that utilizes high conductive metal material and that is generally produced by extrusion method. The conventional heat-dissipating device 10 includes a base plate 101, and a plurality of cooling fins 102 extending vertically from an upper surface of the base plate 101. The chipset (not shown) is disposed below the base plate 101 in such a manner to abut tightly against the base plate 101 such that the heat generated due to operation of the chipset is transferred to the cooling fins 102 via the base plate 101.

In order to maintain tight engagement between the chipset and the base plate 101, a fastening member 11 is usually used in the conventional heat-dissipating device 10.

The fastening member 11 is made from an elongated metal wire that is twisted and bent, and includes a middle wire section 111 and two distal wire sections 112. The middle wire section 111 is disposed at lower ends of the cooling fins 102 so as to fix the base plate 101 within the conventional heat-dissipating device 10. Each of the distal wire sections 112 is formed with a hook for engaging a chipset seat or a holding element of the printed circuit board so as to dispose the base plate 101 in tight abutment with the chipset, thereby transferring and conducting the heat from the chipset toward the cooling fins 102.

FIG. 2 is a lateral side view illustrating how the fastening member 11 fastens the base plate 101 onto the printed circuit board in the conventional heat-dissipating device 10. Some of the cooling fins 102a are formed with protrusions 103 at the lower ends thereof. The protrusion 103 of the respective cooling fin 102a cooperates with the upper surface of the base plate 101 to define a gap therebetween.

In use, the middle wire section 111 of the fastening member 11 is inserted into the gap of the cooling fins 102a. Since each of the distal wire sections 112 define an angle with the middle wire section 111 in a plane transverse to the base plate 101, the distal wire sections 112 can be pressed downward so as to engage the aforementioned chipset seat or the holding element, thereby retaining the base plate 101 securely on the chipset.

It is noted that the spacing distance S1 or S2 between two adjacent cooling fins 102, 102a is increased due to presence of the protrusion 103 at the lower end of the respective cooling fin 102a. Moreover, the increased distance S1 or S2 facilitates mounting of or removal of the middle wire section 111 to and from the protrusions 103 of the cooling fins 102a.

As is known in the art, the larger the contact area of the cooling fins 102 is exposed to the atmosphere, the more heat dissipating efficiency the conventional heat-dissipating device 10 may have. Increase in the spacing distance S1 or S2 results in the decrease in the numbers of the cooling fins 102, which, in turn, lowers adversely the heat dissipating ability of the conventional heat-dissipating device 10.

The more the electronic technology advances, the chipsets are disposed in the trend to be produced in compact size as well as in the multifunction direction. The heat generated from these chipsets is tremendously high, and causes a burden for the chipset. Therefore, it is the object of the manufacturers to produce the electron devices in the compact size within the allowed and limited space of the electronic device.

### SUMMARY OF THE INVENTION

The object of the present invention is to provide a fastening member for use in a heat-dissipating device such that the fastening member can easily and stably secure a base plate without altering the structure of the heat-dissipating device.

In one aspect of the present invention, a fastening member is provided for use in a heat-dissipating device that includes a base plate for disposing on a mounting surface and a plurality of cooling fins extending upwardly from the base plate to define a first channel and a second channel on an upper surface of the base plate. The fastening member includes a first portion adapted to be disposed in the first channel and having an engaging element for engaging a lower surface of the base plate adjacent to one end thereof, a second portion adapted to be disposed in the second channel and extending integrally from the first portion, and a third portion extending integrally from the second portion. The first and second portions are located in a plane, which cooperates with the third portion to define an angle between the plane and the third portion. The third portion has a hook for securing the base plate onto the mounting surface.

In a second aspect of the present invention, a fastening member is provided for use in a heat-dissipating device that includes a base plate and a plurality of cooling fins extending upwardly from the base plate to define a first channel and a second channel on an upper surface of the base plate. The fastening member is adapted to be disposed in the first and second channels and having two ends, each of which is formed with a hook for fixing the base plate onto a mounting surface. The fastening member further includes an engaging element for engaging a lower surface of the base plate adjacent to one end thereof. The engaging element is adapted to be exposed from the cooling fins at the one end of the base plate.

### BRIEF DESCRIPTION OF THE DRAWINGS

Other features and advantages of this invention will become more apparent in the following detailed description of the preferred embodiments of this invention, with reference to the accompanying drawings, in which:

FIG. 1 is a perspective and exploded view of a conventional heat-dissipating device;

FIG. 2 is a lateral side view of the conventional heat-dissipating device;

FIGS. 3A and 3B respectively show exploded and perspective views of the first embodiment of a heat-dissipating device of the present invention;

FIG. 4A is a lateral side view of the first embodiment of the heat-dissipating device of the present invention shown in FIG. 3B;

FIG. 4B is a top view of the first embodiment of the heat-dissipating device of the present invention shown in FIG. 3B;

FIGS. 5 is an exploded view of the second embodiment of the heat-dissipating device of the present invention;

FIG. 6A is a lateral side view of the second embodiment of the heat-dissipating device of the present invention shown in FIG. 5;

FIG. 6B is a top view of the second embodiment of the heat-dissipating device of the present invention shown in FIG. 5; and

FIGS. 7 and 8 respectively show two modifications of a fastening member 6 employed in the heat-dissipating device of the present invention.

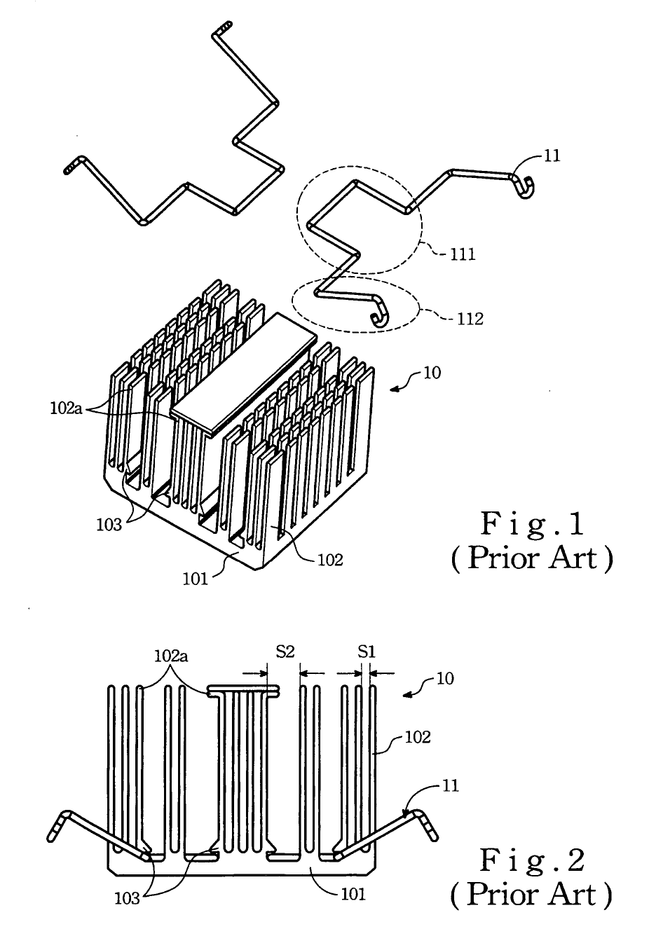

### DETAILED DESCRIPTIONS OF THE PREFERRED EMBODIMENTS

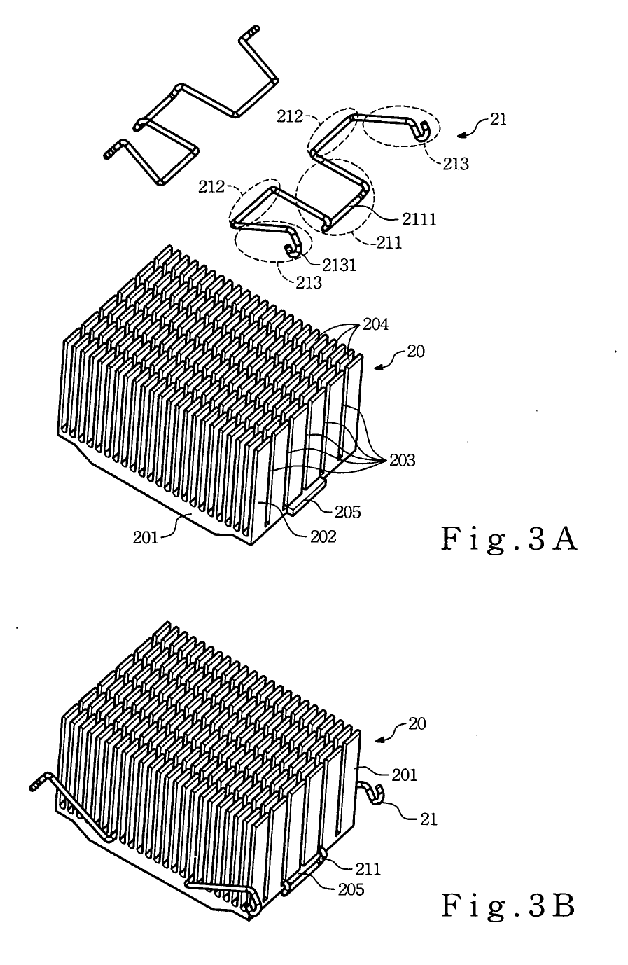

FIGS. 3A and 3B respectively show exploded and perspective views of the first embodiment of a heat-dissipating device 20 of the present invention, and includes two fastening members 21.

The heat-dissipating device 20 is generally made from high conductive metal materials, such as aluminum, copper or brass. The first embodiment of the heat-dissipating device 20 is preferably produced by extrusion method, and includes a base plate 201 and a plurality of cooling fins 202 extending upwardly or vertically from the base plate 201. The base plate 201 can be integrally formed or separately formed with the cooling fins 202. A heat-generating member (not visible) is disposed below the base plate 201 in such a manner to be in tight abutment with the base plate 201. In the first embodiment, a chipset serves as the heat-generating member and generates intensive heat during operation. The intensive heat is transferred to the base plate 201 due to tight abutment, is latter to the cooling fins 202 which dissipate the intensive to an outside environment. The cooling fins 202 are formed on the base plate 201 in array and define a gap between adjacent two of the cooling fins 202. In other words, the cooling fins 202 define a first channel 203 and a second channel 204 on an upper surface of the base plate 201. Each of the first and second channels 203, 204 extends in a direction perpendicular to each other.

The fastening members 21 fastens the base plate 201 securely on the chipset (not shown). Each of the fastening members 21 is made from metal materials, such as alloy or stainless steel, and has flexibility and a restoration force so that its initial shape may change upon receipt of an applied force. The fastening member 21 can retrieve its initial shape when the applied force is removed. Each of the fastening members 21 is formed by bending and twisting an elongated metal string, and includes a first portion 211, a second portion 212 and a third portion 213. The first portion 211 is disposed in the first channel 203, and has an engaging element 2111 for engaging a lower surface of the base plate adjacent to one end thereof (see FIG. 3B). The second portion 212 is disposed in the second channel 204, and extends integrally from the first portion 211. The third portion 213 extends integrally from the second portion 212. The first and second portions 211, 212 are located in a plane, which cooperates with the third portion 213 to define an angle lesser than 180°. The degrees of aforementioned angle can be altered depending on the type of metal from which the fastening member 21 is constructed. The third portion 213 has a hook 2131 for securing the base plate 201 onto the mounting surface (not shown). Preferably, the hook 2131 of the third portion 213 has a C-shaped configuration when viewed from one specific viewing angle.

Referring to FIG. 3B, when the fastening members 21 are utilized in the heat-dissipating device 20 of the present invention, the engaging element 2111 of the first portion 211 is exposed from the cooling fins 202 at one end of the base plate 201 for engaging the lower surface thereof. The base plate 201 has a projection 205 protruding outwardly from the end to permit engagement of the engaging element 2111 of the first portion 211 in order to secure the base plate 201 tightly onto the mounting surface of a printed circuit board (not shown).

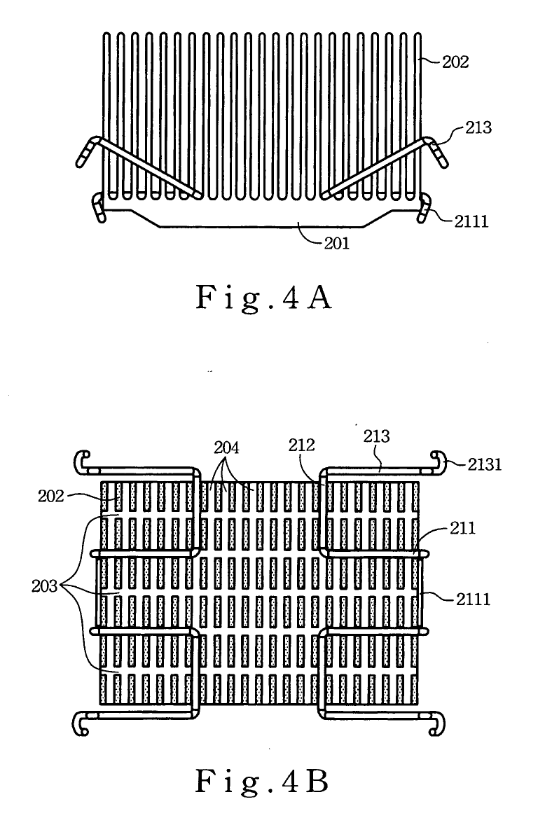

FIGS. 4A and 4B are lateral side and top views of the first embodiment of the heat-dissipating device of the present invention shown in FIG. 3B. From these Figures, one can observe that the first portion 211 extends in the first channel 203, the second portion 212 extends in the second channel 204 and while the engaging element 2111 of the first portion 211 is exposed from one end of the base plate 201.

Furthermore, the first and second portions 211, 212 located in the first plane can be arranged to define 90°. The second and third portions 212, 213 cooperatively define 90° therebetween. Since each of the fastening members has several bent ports and when the fastening members 21 are disposed on the base plate 201 in order to secure the same, the base plate 201 is prevented from moving in the opposite sides since the first and second portions 211, 212 are confined in the first and second channels 203, 204 of the cooling fins 202. After assembly of the fastening members 21 on the base plate 201, the first portion 211 and the third portion 213 provides two counteract forces that press the base plate 201 tightly against the mounting surface so as to provide stability of the base plate 201 on the mounting surface. Note that mounting of the base plate 201 on the mounting surface by u sing the fastening members 21 can be conducted easily. The structure of the base plate 201 and the cooling fins 202 needs not be altered unlike to the prior art heat-dissipating device. Therefore, the manufacturing cost for producing the heat-dissipating device of the present invention can be reduced remarkably. In the heat-dissipating device of the present invention, the number of the cooling fans can be increased or the spacing distance between adjacent two of the cooling fins can be altered so as to enhance the heat dissipating ability.

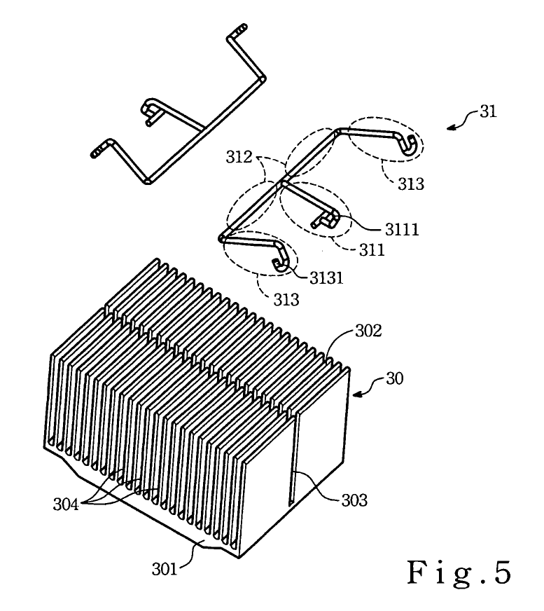

FIG. 5 shows the second embodiment of the heat-dissipating device of the present invention, and includes a base plate 301 and a plurality of cooling fins 302 extending vertically from an upper surface of the base plate 301 to define the first channel 303 and the second channel 304 transverse to the first channel 303. Each of the fastening members 31 has a first portion 311, a second portion 312 and a third portion 313. The first portion 311 is disposed in the first channel 303, and has an engaging element 3111 for engaging the lower surface of the base plate 301 adjacent to one end thereof. The second portion 312 is disposed in the second channel 304, and extends integrally from the first portion 311. The third portion 313 extends integrally from the second portion 312. The first and second portions 311, 312 are located in the same plane, which cooperates with the third portion 313 to define an angle lesser than 180°. The degrees of aforementioned angle can be altered depending on the type of metal from which the fastening member 31 is constructed. The third portion 313 has a hook 3131 for securing the base plate 301 onto the mounting surface (not shown).

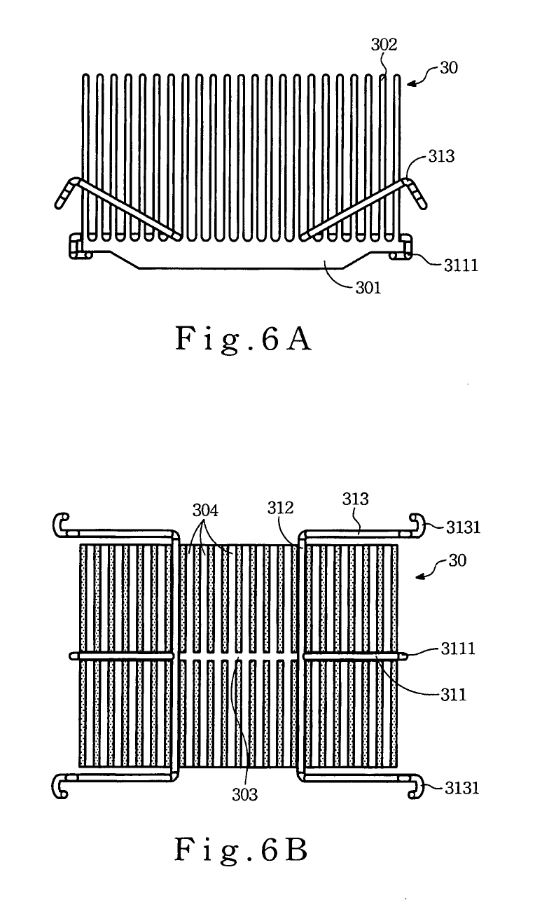

FIGS. 6A and 6B are lateral side and top views of the second embodiment of the heat-dissipating device of the present invention shown in FIG. 5. From these Figures, one can observe that the first portion 311 extends in the first channel 303, the second portion 312 extends in the second channel 304 and while the engaging element 3111 of the first portion 311 is exposed from one end of the base plate 301. The first and second portions 311, 312 are located in the same plane and can be arranged to define 90° therebetween. The second and third portions 312, 313 can be arranged to define 90° therebetween. When the fastening members 31 are disposed on the base plate 301 in order to secure the same, the base plate 301 is prevented from moving in the opposite sides since the first and second portions 311, 312 are confined in the first and second channels 303, 304 of the cooling fins 302. After assembly of the fastening members 31 on the base plate 301, the first portion 311 and the third portion 313 provide two counteract forces that press the base plate 301 tightly against the mounting surface.

Note that in the second embodiment, the configuration of the cooling fins 302 is somewhat changed and the structure of the fastening members 31 is consequently changed so as to dispose the first and second portions 311, 312 in the first and second channels 303, 304 defined by the cooling fins 302 on the upper surface of the base plate 301.

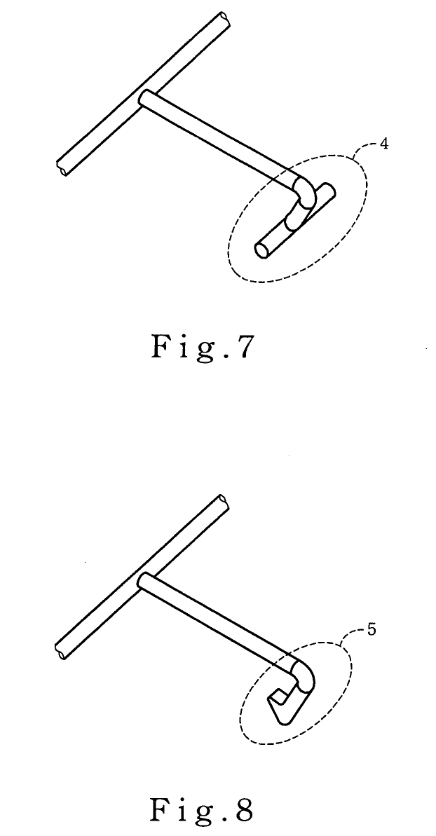

The structure of the fastening members should not to limited only to the above embodiments. However, the spirit and scope of the present invention should encompass many other modifications as shown in FIGS. 7 and 8.

Referring to FIGS. 7 and 8, the engaging element 4, 5 of the fastening member is shaped as a “T” or an inverted “J” Letters respectively so long as it can engage the lower surface of the base plate 301.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

What is claimed is:

1. A fastening member for a heat-dissipating device that includes a base plate and a plurality of cooling fins extending upwardly from the base plate to define a first channel and a second channel on an upper surface thereof, the fastening member comprising:
a first portion adapted to be disposed in the first channel, and having an engaging element for engaging a lower surface of the base plate adjacent to one end thereof;
a second portion adapted to be disposed in the second channel and extending integrally from said first portion; and
a third portion extending integrally from said second portion, said first and second portions being located in a first plane, which cooperates with said third portion to define an angle, said third portion having a hook for securing the base plate onto a mounting surface.

2. The fastening member according to claim 1, wherein said first and second portions cooperatively define 90° therebetween, said second and third portions cooperatively defining 90° therebetween.

3. The fastening member according to claim 1, wherein the fastening member is in the form of a string and is formed by bending and twisting an elongated metal string in order to achieve said first, second and third portions.

4. The fastening member according to claim 1, wherein said hook of said third portion has a C-shaped configuration when viewed from one specific viewing angle.

5. The fastening member according to claim 1, wherein said engaging element of said first portion is exposed from the cooling fins at the end of the base plate.

6. The fastening member according to claim 5, wherein the base plate has a projection protruding outwardly from the end to permit engagement of said engaging element of said first portion in order to secure the base plate tightly onto the mounting surface.

7. The fastening member according to claim 1, wherein each of said first and second channels extends in a direction perpendicular to each other.

8. A fastening member for use in a heat-dissipating device that includes a base plate and a plurality of cooling fins extending upwardly from the base plate to define a first channel and a second channel on an upper surface of the base plate, the fastening member being disposed in the first and second channels and having two ends, each of which is formed with a hook for fixing the base plate onto a mounting surface, the fastening member further comprising:
an engaging element for engaging a lower surface of the base plate adjacent to one end thereof, said engaging element being exposed from the cooling fins at the one end of the base plate.

9. The fastening member according to claim 1, wherein the fastening member is in the form of a string and is formed by bending and twisting an elongated metal string.

10. The fastening member according to claim 8, wherein the base plate has a projection protruding outwardly from the one end to permit engagement of said engaging element in order to secure the base plate tightly on the mounting surface.

11. The fastening member according to claim 8, wherein each of the first and second channels extends in a direction perpendicular to each other.
